(19) United States
(12) Patent Application Publication
(10) Pub. No.: US 2026/0343955 A1
(43) Pub. Date: Oct. 29, 2026

(54) THIN FILM TRANSISTOR STRUCTURE

(71) Applicant: Taiwan Semiconductor Manufacturing Company, Ltd., Hsinchu (TW)

(72) Inventors: Wu-Wei Tsai, Taoyuan City (TW); Hai-Ching Chen, Hsinchu City (TW); Po-Ting Lin, Taichung City (TW); Yan-Yi Chen, Taipei City (TW); Yu-Ming Lin, Hsinchu City (TW); Chung-Te Lin, Tainan City (TW); Tzer-Min Shen, Hsinchu City (TW); Yen-Tien Tung, Hsinchu (TW)

(21) Appl. No.: 19/732,800

(22) Filed: Jul. 7, 2026

Related U.S. Application Data
(62) Division of application No. 18/316,439, filed on May 12, 2023.

(51) Int. Cl. H10D 30/67; H10D 30/01; H10D 84/83

(52) U.S. Cl. CPC H10D 30/6757; H10D 30/031; H10D 30/673; H10D 84/83

(57) ABSTRACT

The problem of providing transistors that can be manufactured to any specified threshold voltage withing a broad range of threshold voltages without creating leakage, capacitance, or process compatibility issues is solved by introducing a buried layer of a second dielectric composition into a gate dielectric of a first dielectric composition. The second dielectric composition is selected relative to the first dielectric composition so that dipoles form around the interface of the two dielectrics. The dipoles create an electric field that causes a shift in the threshold voltage. The buried layer has a higher dielectric constant than the gate dielectric, is thinner than the gate dielectric, and is proximate the channel.

### REFERENCE TO RELATED APPLICATION

This Application is a Divisional of U.S. application Ser. No. 18/316,439, filed on May 12, 2023, the contents of which are hereby incorporated by reference in their entirety.

### BACKGROUND

The integrated circuit (IC) manufacturing industry has experienced exponential growth over the last few decades. As ICs have evolved, functional density (i.e., the number of interconnected devices per unit chip area) has generally increased while geometric size (i.e., the smallest component that can be created) has generally decreased. Another development is BCD technology which is a combination of bipolar junction transistor (BJT) technology, complementary metal-oxide-semiconductor (CMOS) technology, and double-diffused metal-oxide-semiconductor (DMOS) technology. BCD technology allow logic, analog, and power devices to be formed on a single semiconductor chip. BCD technology creates challenges in its needs for process compatibility and for limiting the proliferation of process steps.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-2 illustrate cross-sectional side views of bottom gate transistors according to some embodiments of the present disclosure.

FIG. 3 provides an expanded view of a portion of FIG. 2.

FIGS. 4-6 illustrate cross-sectional side views of bottom gate transistors according to some other embodiments.

FIGS. 7-8 illustrate cross-sectional side views of top gate transistors according to some embodiments of the present disclosure.

FIG. 9 provides an expanded view of a portion of FIG. 8.

FIGS. 10-12 illustrate cross-sectional side views of bottom gate transistors according to some other embodiments.

FIG. 13-14 illustrate cross-sectional side views of integrated circuit (IC) devices according to some embodiments of the present disclosure.

FIGS. 15-30 are a series of cross-sectional view illustrations exemplifying a method according to the present disclosure of forming a device such as the device of FIG. 13.

FIGS. 31-41 are a series of cross-sectional view illustrations exemplifying a method according to the present disclosure of forming a device such as the device of FIG. 14.

FIGS. 42-43 provide flow charts illustrating some methods according to the present disclosure of forming IC devices according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The problem of providing transistors that can be manufactured to any specific threshold voltage withing a broad range of threshold voltages without creating leakage, capacitance, or process compatibility issues is solved by introducing a buried layer of a second dielectric composition into a gate dielectric of a first dielectric composition. The second dielectric composition is selected relative to the first dielectric composition so that dipoles form around the interface between the two dielectric compositions. The dipoles create an electric field that causes a shift in the threshold voltage. The threshold voltage shift can be positive or negative according to the orientation of the dipoles and whether the semiconductor channel is p-type or n-type.

The effect of the dipoles is increased as they are brought closer to the semiconductor channel. In some embodiments, the buried layer is closer to the semiconductor channel than it is to the gate electrode. In some embodiments, half or more of the gate dielectric structure lies between the buried layer and the gate electrode. In some embodiments, a distance between the buried layer and the gate electrode is greater than a thickness of the buried layer.

In some embodiments, the buried layer has a higher dielectric constant than the gate dielectric. In some embodiments, the gate dielectric is silicon dioxide or the like. In some embodiments, the buried layer is a high-κ dielectric. Materials with higher dielectric constants are more suitable for the buried layer. The thickness of the buried layer is limited so that its effect on gate capacitance is also limited.

In some embodiments, both the gate dielectric and the buried layer are oxides, and the buried layer has an electronegativity that is distinct from that of the gate dielectric. A large difference in electronegativity between these dielectric compositions facilitates the formation of dipoles. In some embodiments, the electronegativity difference is at least as large as the electronegativity difference between silicon dioxide (SiO₂) and hafnium oxide (HfO₂). In some embodiments, the electronegativity difference is greater than the electronegativity difference between silicon dioxide (SiO₂) and hafnium oxide (HfO₂).

In some embodiments, both the gate dielectric and the buried layer are oxides, and the buried layer has an oxygen areal density that is distinct from that of the gate dielectric. A large difference in oxygen areal density between these dielectric compositions facilitates the formation of dipoles. In some embodiments, the oxygen areal density difference is at least as large as the oxygen areal density difference between silicon dioxide (SiO₂) and hafnium oxide (HfO₂). In some embodiments, the oxygen areal density difference is greater than the oxygen areal density difference between silicon dioxide (SiO₂) and hafnium oxide (HfO₂).

In some embodiments, the buried layer comprises a mixture of two or more dielectrics. Mixing two or more dielectrics allows fine tuning of the threshold voltage. In some embodiments, the buried layer comprises a mixture of two dielectrics both of which have a higher oxygen areal density than the gate dielectric. For example, if the gate dielectric is silicon dioxide (SiO₂), the buried layer may be a mixture of two or more of gallium oxide (Ga₂O₃), indium oxide (In₂O₃), zinc oxide (ZnO), aluminum oxide (Al₂O₃), titanium oxide (TiO₂), hafnium oxide (HfO₂), or the like. In some embodiments, the buried layer comprises a mixture of two dielectrics both of which have a lower oxygen areal density than the gate dielectric. For example, if the gate dielectric is silicon dioxide (SiO₂), the buried layer may be a mixture of two or more of yttrium oxide (Y₂O₃), strontium oxide (SrO), lanthanum oxide (La₂O₃), or the like. Depending on whether the buried layer has a higher or lower oxygen areal density than the gate dielectric, the threshold voltage is either increased or decreased. Making the dielectrics in the buried layer have oxygen areal densities that are either both higher or both lower than the oxygen areal density of the gate dielectric ensures that the two dielectric operate in conjunction.

In some embodiments, a second buried layer is buried in the gate dielectric. In some embodiments, the second buried layer is adjacent to the first buried layer. In some embodiments, the second buried layer is spaced apart from the first buried layer by a thin layer of the gate dielectric. Two buried layers provide a great threshold voltage shift than one. Moreover, the inventors have found that two buried layers of distinct compositions can provide a greater threshold voltage shift than can be achieved with a single buried layer composition.

In some embodiments, the transistor is a top gate device. The top gate device may have a channel provided by a crystal substrate such as a silicon crystal substrate. In a manufacturing process of the present disclosure, a thin layer of the gate dielectric is deposited first, followed by the buried layer, followed by a remaining portion of the gate dielectric, deposition of the gate electrode, formation of spacers, and doping of source/drain regions. The thin layer of the gate dielectric may prevent undesirable interactions between the buried layer and the substrate. Controlling the threshold voltage using the buried layer may prevent undesirable variations in the transistor height and increase compatibility with the formation of other device structures on the same semiconductor substrate.

In some embodiments, the transistor is a bottom gate device. The bottom gate device may have a channel provided by a deposited layer such as amorphous silicon, polysilicon, or a metal oxide semiconductor. In a manufacturing process of the present disclosure, the gate dielectric is deposited first, followed by the buried layer, and the channel layer. The gate stack is patterned followed by formation of spacers, deposition of an interlevel dielectric layer, and formation of source and drain regions within the interlevel dielectric. A thin layer of the gate dielectric layer may be deposited over the buried layer to prevent interactions with the semiconductor channel. Controlling the threshold voltage using the buried layer may prevent undesirable variations in the transistor height and facilitate integration of the transistor within a metal interconnect structure.

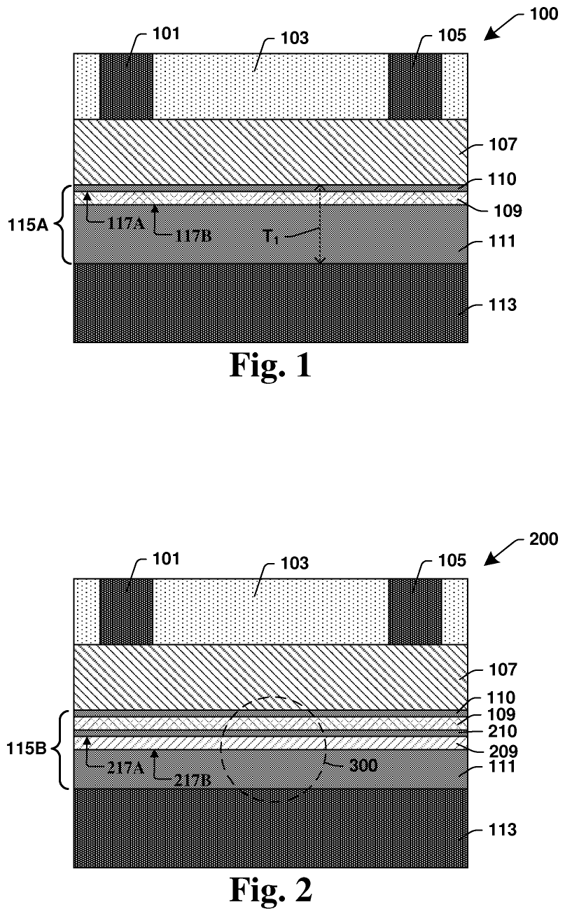

FIG. 1 is a cross-sectional view illustration of a transistor 100 according to some embodiments. The transistor 100 comprises a gate dielectric structure 115A between a bottom gate electrode 113 and a channel layer 107. A source region 101 and a drain region 105 which are conductive structures within an interlevel dielectric (ILD) layer 103 may be disposed above the channel layer 107. The gate dielectric structure 115A includes a buried layer 109 within a gate dielectric 111. A thin layer 110 of the gate dielectric 111 separates the buried layer 109 from the channel layer 107.

The buried layer 109 is embedded within the gate dielectric 111 so that a first interface 117A forms between the buried layer 109 and the thin layer 110 and a second interface 117B forms between the buried layer 109 and a bulk region of the gate dielectric 111. The interaction of the buried layer 109 with the gate dielectric 111 at the first interface 117A and at the second interface 117B shifts a threshold voltage for the transistor 100 to a much larger degree than can be explained in terms of the thickness and dielectric constant of the buried layer 109. The primary mechanism for this shift may be the formation of dipoles around the first interface 117A and around the second interface 117B.

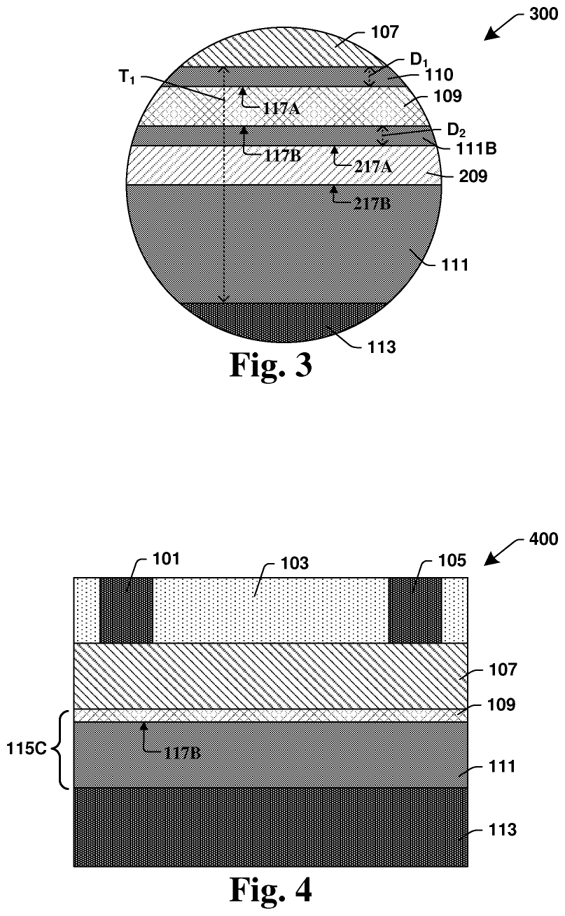

The buried layer 109 is closer to the channel layer 107 than it is to the bottom gate electrode 113. The buried layer 109 is separated from the channel layer 107 by a distance D₁ (see FIG. 3), which is a thickness of the thin layer 110. In some embodiments, the distance D₁ is about equal to a thickness of the buried layer 109. In some embodiments, the distance D₁ is less than a thickness of the buried layer 109. In some embodiments, the distance D₁ is from about 1 Angstrom to about 10 Angstroms. In some embodiments, the distance D₁ is from about 1 Angstrom to about 5 Angstroms.

In some embodiments, a thickness T₁ of the of the gate dielectric structure 115A is from about 1 to about 10 nm. The thickness of the buried layer 109 is less than half the thickness T₁. In some embodiments, the thickness of the buried layer 109 plus that of the thin layer 110 is less than half the thickness T₁. In some embodiments, the thickness of the buried layer 109 is about one fourth or less the thickness T₁. In some embodiments, the thickness of the buried layer 109 is from about 1 Angstrom to about 10 Angstroms.

The buried layer 109 has a higher dielectric constant than the gate dielectric 111. In some embodiments, the buried layer 109 is a high-κ dielectric. In some embodiments, the buried layer 109 is or comprises an oxide. The buried layer 109 may be or comprise, for example, aluminum oxide (Al₂O₃), titanium oxide (TiO₂), hafnium oxide (HfO₂), zinc oxide (ZnO), yttrium oxide (Y₂O₃), lanthanum oxide (La₂O₃), gallium oxide (Ga₂O₃), indium oxide (In₂O₃), a combination thereof, or the like. In some embodiments, the buried layer 109 has a single dielectric composition. In some embodiments, the buried layer 109 is a mixture of two or more dielectrics. Mixing two or more dielectrics in the buried layer 109 allows fine tuning of the threshold voltage.

The gate dielectric 111 may have any suitable composition. In some embodiments, the gate dielectric 111 is or comprises an oxide. The gate dielectric 111 may be or comprise, for example, silicon oxide (SiO₂), aluminum oxide (Al₂O₃), hafnium oxide (HfO₂), zirconium oxide (ZrO₂), lanthanum oxide (La₂O₃), strontium oxide (SrO), a combination thereof, or the like. Where the gate dielectric 111 is a mixture of two or more oxides, the oxides may be mixed homogeneously or may be arranged in alternating layers. If the oxides are arranged in alternating layers, the individual layers are thinner than the buried layer 109. In some embodiments, the gate dielectric 111 is silicon oxide (SiO₂) or the like.

FIG. 2 is a cross-sectional view illustration of a transistor 200 according to some embodiments. FIG. 3 provides an expanded view of an area 300 in FIG. 2. The transistor 200 is like the transistor 100 of FIG. 1 except that the transistor 200 has of a gate dielectric structure 115B. The gate dielectric structure 115B is like the gate dielectric structure 115A of FIG. 1 except that the gate dielectric structure 115B has a second buried layer 209. A second thin layer 210 of the gate dielectric 111 separates the second buried layer 209 from the buried layer 109.

The second buried layer 209 is embedded within the gate dielectric 111 so that a third interface 217A forms between the second buried layer 209 and the second thin layer 210 and a fourth interface 217B forms between the second buried layer 209 and a bulk region of the gate dielectric 111. The interaction of the second buried layer 209 with the gate dielectric 111 at the third interface 217A and at the fourth interface 217B shifts a threshold voltage for the transistor 100 to a much larger degree than can be explained in terms of the thickness and dielectric constant of the second buried layer 209.

The second buried layer 209 is closer to the channel layer 107 than it is to the bottom gate electrode 113. The second buried layer 209 is separated from the buried layer 109 by a distance D₂ (see FIG. 3), which is a thickness of the second thin layer 210. In some embodiments, the distance D₂ is about equal to a thickness of the second buried layer 209. In some embodiments, the distance D₂ is less than a thickness of the second buried layer 209. In some embodiments, the distance D₂ is from about 1 Angstrom to about 10 Angstroms. In some embodiments, the distance D₂ is from about 1 Angstrom to about 5 Angstroms.

The thickness and composition options for of the second buried layer 209 are the same as those for the buried layer 109. In some embodiments, the second buried layer 209 has a distinct composition from the buried layer 109. In some embodiments, the combined thicknesses of the thin layer 110, the buried layer 109, the second thin layer 210, and the second buried layer 209 are less than half the thickness T₁ of the gate dielectric structure 115B.

The channel layer 107 is a semiconductor and may have any suitable composition. Examples of compositions that may be suitable include amorphous silicon, polysilicon, a metal oxide semiconductor, or the like. Examples of metal oxide semiconductors that may be used include, without limitation, indium zinc oxide (IZO), indium gallium oxide (IGO), indium gallium zinc oxide (IGZO), indium tungsten oxide (IWO), indium tungsten zinc oxide (IWZO), indium gallium zinc tin oxide (IGZTO), zinc oxide (ZnO), indium tin oxide (InSnO or ITO), combinations thereof, or the like.

In some embodiments, the channel layer 107 is a metal oxide semiconductor. The thin layer 110 may be operative to prevent undesirable interactions between a channel layer 107 that is silicon and a buried layer 109 that is a high-κ dielectric. Selecting a suitable metal oxide semiconductor for the channel layer 107 is an alternate way of preventing such undesirable interactions.

FIG. 4 is a cross-sectional view illustration of a transistor 400 according to another embodiment. The transistor 400 is like the transistor 100 of FIG. 1 except that the transistor 200 has a gate dielectric structure 115C. The gate dielectric structure 115C is like the gate dielectric structure 115A of FIG. 1 except that in the gate dielectric structure 115C the thin layer 110 (see FIG. 1) is absent and the buried layer 109 abuts the channel layer 107. The gate dielectric structure 115C has the second interface 117B but not the first interface 117A (see FIG. 1).

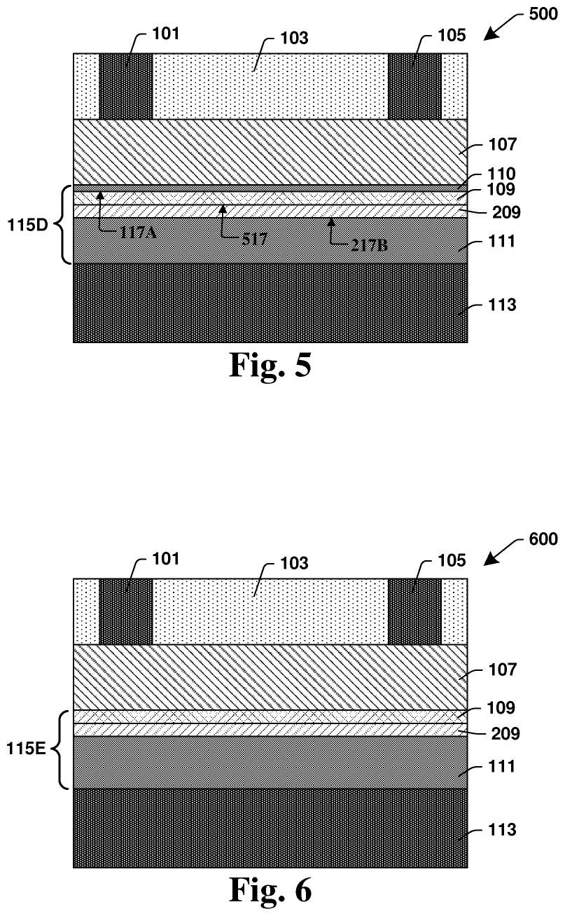

FIG. 5 is a cross-sectional view illustration of a transistor 500 according to another embodiment. The transistor 500 is like the transistor 200 of FIG. 2 except that the transistor 500 has a gate dielectric structure 115D. The gate dielectric structure 115D is like the gate dielectric structure 115B of FIG. 2 except that in the gate dielectric structure 115D that second thin layer 210 is absent and the buried layer 109 abuts the second buried layer 209 to form an interface 517. In the transistor 500, the buried layer 109 and the second buried layer 209 have distinct compositions and there are three interfaces at which dipoles may form: the first interface 117A, the interface 517, and the fourth interface 217B.

FIG. 6 is a cross-sectional view illustration of a transistor 600 according to another embodiment. The transistor 600 is like the transistor 500 of FIG. 5 except that the transistor 500 has a gate dielectric structure 115E. The gate dielectric structure 115E is like the gate dielectric structure 115D of FIG. 5 except that in the gate dielectric structure 115E the thin layer 110 that separates the buried layer 109 from the channel layer 107 is absent. In the transistor 600, the buried layer 109 may function like the thin layer 110 in the gate dielectric structure 115A of FIG. 1. Each of the gate dielectric structures 115A-115E of FIGS. 1-2 and 4-6 may provide unique advantages in terms of varying the threshold voltage while keeping the capacitance within a desired range.

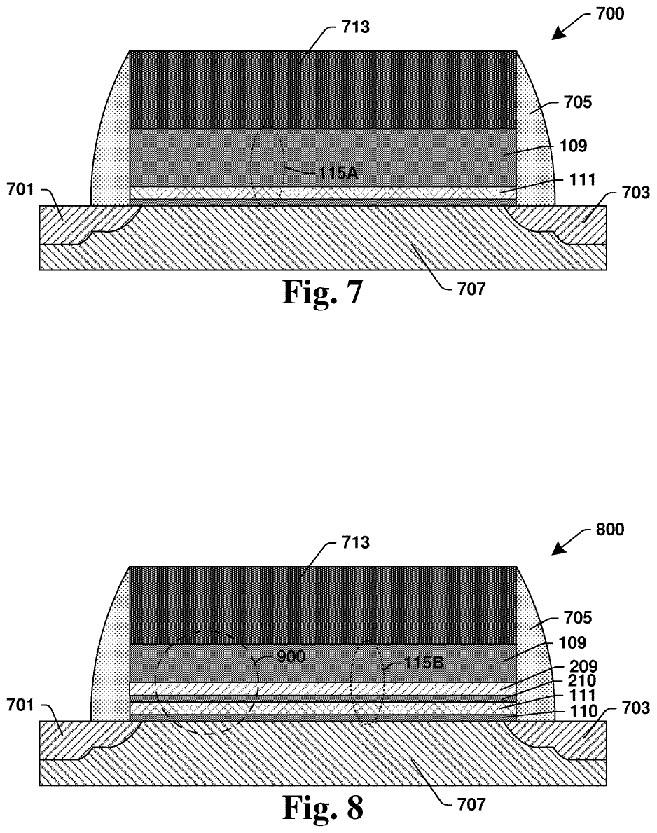

FIGS. 7-12 are cross-sectional views of top gate transistors that correspond to the bottom gate transistors of FIGS. 1-6 and use the same gate dielectric structures. FIG. 7 illustrates a top gate transistor 700 that uses the gate dielectric structure 115A. For the top gate transistor 700 the gate dielectric structure 115A is inverted so that the buried layer 109 is proximate a semiconductor substrate 707, which provides the channel. A gate electrode 713 is above the gate dielectric structure 115A. A source region 701 and a drain region 703 are provided by regions of the semiconductor substrate 707 that have opposite doping type and are aligned to sidewall spacers 705.

The semiconductor substrate 707 may be any suitable type. The semiconductor substrate 707 may be, for example, a bulk substrate (e.g., a bulk silicon substrate) or a silicon-on-insulator (SOI) substrate. The semiconductor may be silicon (Si), a group III-V or some other binary semiconductor, a tertiary semiconductor (e.g., AlGaAs), a higher order semiconductor, or the like. The semiconductor may be a single crystal or an epitaxially grown structure.

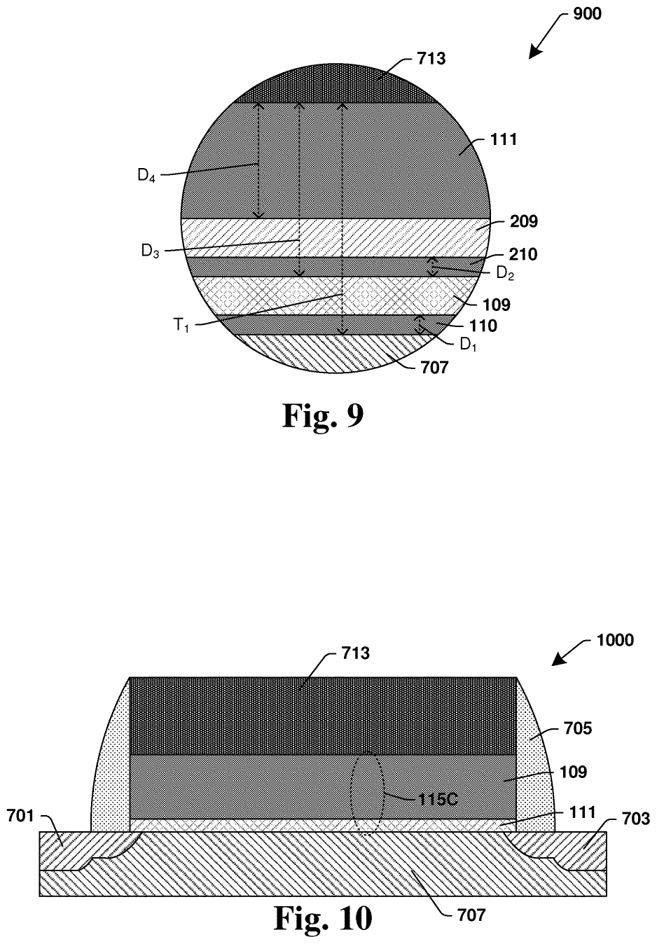

FIG. 8 illustrates a top gate transistor 800 that uses the gate dielectric structure 115B of FIG. 2. FIG. 9 illustrates the area 900 of FIG. 8. As shown in FIG. 9, the dimensions of the gate dielectric structure 115B are the same as shown in FIG. 3. The only difference is that the gate dielectric structure 115B is inverted for the top gate transistor 800.

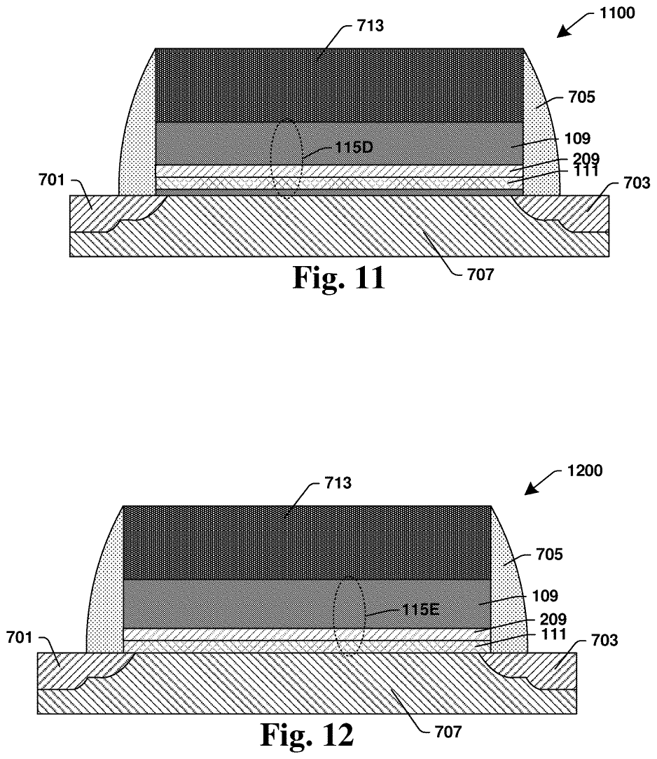

FIG. 10 illustrates a top gate transistor 1000 that uses the gate dielectric structure 115C of FIG. 4. As shown by this example, the thin layer 110 (see FIG. 7) separating the buried layer 109 from the semiconductor substrate 707 is optional although the material choices that make eliminating the thin layer 110 feasible are more likely to be suitable for a bottom gate transistor. FIG. 11 illustrates a top gate transistor 1100 that uses the gate dielectric structure 115D of FIG. 5 and FIG. 12 illustrates a top gate transistor 1200 that uses the gate dielectric structure 115E of FIG. 6.

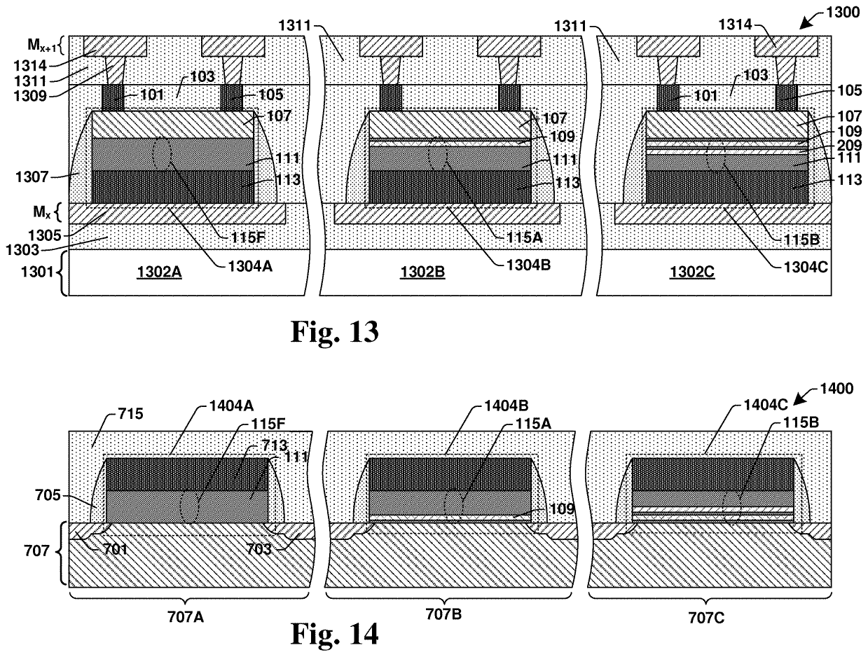

FIG. 13 provides a cross-sectional view illustration of an integrated circuit (IC) device 1300 that includes a bottom gate transistor 1304A, a bottom gate transistor 1304B, and a bottom gate transistor 1304C. The bottom gate transistors 1304A-1304C are formed over substrate regions 1302A-1302C respectively. The substrates regions 1302A-1302C may be regions of three distinct substrates or may be different regions on a single substrate 1301. The substrate 1301 may comprise a semiconductor substrate and may include one or more metal interconnect layers formed over that semiconductor substrate. The bottom gate transistors 1304A-1304C are illustrated as all being formed between a metallization layer M_{X} and a metallization layer M_{X+1} of a metal interconnect structure.

The bottom gate transistors 1304A-1304C have, respectively, the gate dielectric structure 115F, the gate dielectric structure 115A of FIG. 1, and the gate dielectric structure 115B of FIG. 2. The gate dielectric structure 115F is like the gate dielectric structures 115A and 115B but does not include any buried layers. The gate dielectric structures 115F, 115A, and 115B may all have about the same height. The bottom gate transistors 1304A-1304C may all have approximately the same capacitance and approximately the same footprint while varying widely in threshold voltage. In some embodiments, the threshold voltages are in the range from about 0.1 volt to about 20 volts. In some embodiments, the threshold voltages are in the range from about 1 volt to about 5 volts. As shown by the IC device 1300, buried layers of the present disclosure create design flexibility and modularity by allowing threshold voltages to be varied without making substantial simultaneous variations in transistor widths, thickness, or capacitances.

In some embodiments, one of the bottom gate transistors 1304A-1304C has a threshold voltage that is about 25% or more greater than the threshold voltage of another of the bottom gate transistors 1304A-1304C. In some embodiments, one of the bottom gate transistors 1304A-1304C has a threshold voltage that is about 50% or more greater than the threshold voltage of another of the bottom gate transistors 1304A-1304C. In some embodiments, one of the bottom gate transistors 1304A-1304C has a threshold voltage that is double or more the threshold voltage of another of the bottom gate transistors 1304A-1304C.

FIG. 14 provides a cross-sectional view illustration of an integrated circuit (IC) device 1400 that includes a top gate transistor 1404A, a top gate transistor 1404B, and a top gate transistor 1404C. The top gate transistors 1404A-1404C are formed over substrate regions 707A-707C respectively. The substrates regions 707A-707C may be regions of three distinct substrates or may be different regions on a single semiconductor substrate 707. Where the substrates are distinct, the IC device 1400 may represent three distinct devices produced at one foundry under one set of process constraints. In some embodiments, the semiconductor substrate 707 is P-type substate. In some embodiments, the semiconductor substrate 707 is N-type substate.

The top gate transistors 1404A-1404C have, respectively, the gate dielectric structure 115F, the gate dielectric structure 115A of FIG. 7, and the gate dielectric structure 115B of FIG. 8. The gate dielectric structure 115F is like the gate dielectric structures 115A and 115B but does not include any buried layers. The top gate transistors 1404A-1404C may all have approximately the same capacitance and approximately the same footprint but widely varying threshold voltages. In some embodiments, the voltages are in the range from about 0.1 volt to about 20 volts. In some embodiments, the voltages are in the range from about 1 volt to about 5 volts. As shown by the IC device 1400, buried layers of the present disclosure create design flexibility and modularity for top gate transistors as well as bottom gate transistors. The direction of variation of a threshold voltage cause by insertion of one or both of the buried layer 109 and the second buried layer 209 will vary according to the doping type of the semiconductor substrate 707.

In some embodiments, one of the top gate transistors 1404A-1404C has a threshold voltage that is about 25% or more greater than the threshold voltage of another of the top gate transistors 1404A-1404C. In some embodiments, one of the top gate transistors 1404A-1404C has a threshold voltage that is about 50% or more greater than the threshold voltage of another of the top gate transistors 1404A-1404C. In some embodiments, one of the top gate transistors 1404A-1404C has a threshold voltage that is double or more the threshold voltage of another of the top gate transistors 1404A-1404C.

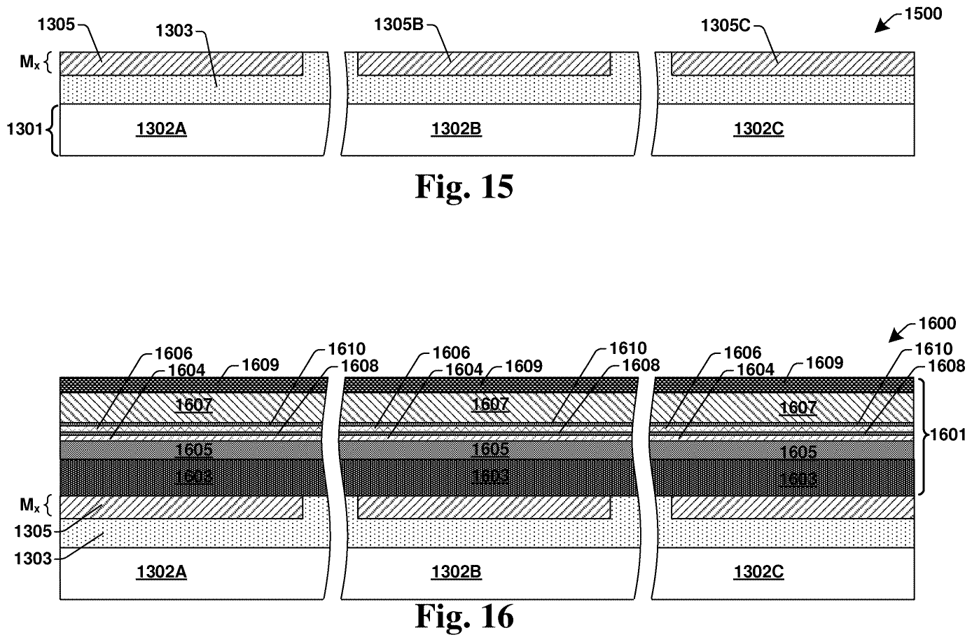

FIGS. 15 through 30 are cross-sectional view illustrations exemplifying a method according to the present disclosure of forming an IC device having transistors according to the present disclosure. While FIGS. 15 through 30 are described with reference to various embodiments of a method, it will be appreciated that the structures shown in FIGS. 15 through 30 are not limited to the method but rather may stand alone separate from the method. FIGS. 15 through 30 are described as a series of acts. The order of these acts may be altered in other embodiments. While FIGS. 15 through 30 illustrate and describe a specific set of acts, some may be omitted in other embodiments. Further, acts that are not illustrated and/or described may be included in other embodiments. While the method of FIGS. 15 through 30 is described in terms of forming the IC device 1300 of FIG. 13 or the like, the method and variations thereof may be used to form other IC devices.

As shown by the cross-sectional view 1500 of FIG. 15, the method may begin with forming the metallization layer M_{X} over the substrate 1301. X is a number greater than or equal to 1 and the substrate 1301 has X−1 metallization layers below the metallization layer M_{X}. The metallization layer M_{X} includes a metal line 1305, a metal line 1305B, and a metal line 1305C over the substrate regions 1302A-1302C respectively. The metal line 1305, 1305B, and 1305C, are surrounded by an interlevel dielectric 1303 and are for making contacts with bottom electrodes. Alternatively, bottom electrode vias may be formed and used to make those contacts.

As shown by the cross-sectional view 1600 of FIG. 16 a gate stack 1601 may be formed over the substrate regions 1302A, 1302B, and 1302C. The gate stack 1601 includes layers corresponding to the transistor 200 of FIG. 2. The gate stack 1601 includes an electrode layer 1603, a gate dielectric layer 1605, a second buried layer 1604, a second thin gate dielectric layer 1608, a first buried layer 1606, a first thin gate dielectric layer 1610, a channel layer 1607, and a hard mask layer 1609. The deposition processes may be atomic layer deposition (ALD), chemical vapor deposition (CVD), physical vapor deposition (PVD), the like, or a combination thereof. In some embodiments, the second buried layer 1604, the second thin gate dielectric layer 1608, the first buried layer 1606, and the first thin gate dielectric layer 1610 are formed by ALD. ALD provided precise control over the thicknesses of these layers.

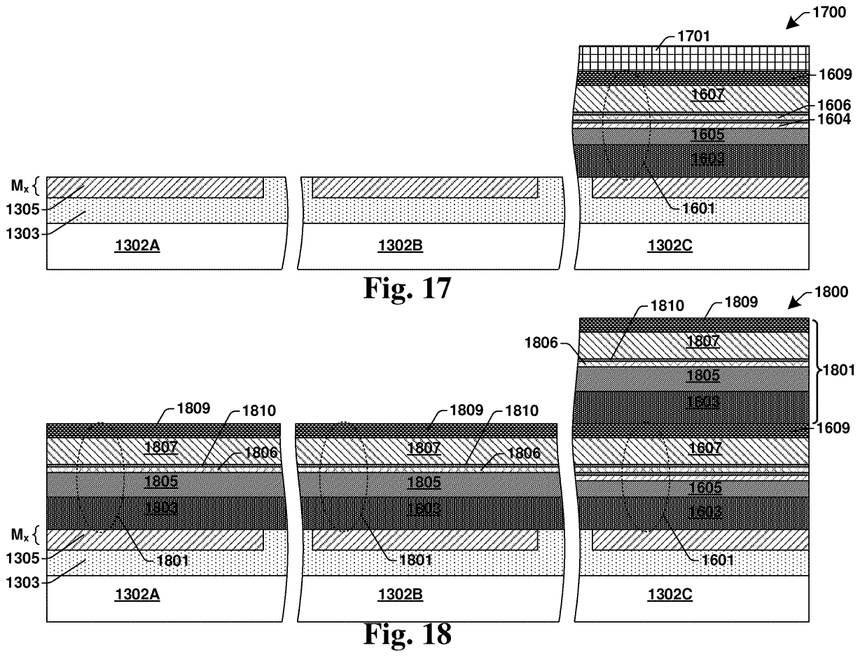

As shown by the cross-sectional view 1700 of FIG. 17, a mask 1701 is formed and used to cover the substrate region 1302C while the gate stack 1601 is etched from the substrate regions 1302A and 1302B. After etching, the mask 1701 is stripped.

As shown by the cross-sectional view 1800 of FIG. 18, a gate stack 1801 is formed over the structure shown by the cross-sectional view 1700 of FIG. 17. The gate stack 1801 forms over the gate stack 1601 in the substrate region 1302C. The gate stack 1801 includes layers corresponding to the transistor 100 of FIG. 1. The gate stack 1801 includes an electrode layer 1803, a gate dielectric layer 1805, a first buried layer 1806, a first thin gate dielectric layer 1810, a channel layer 1807, and a hard mask layer 1809.

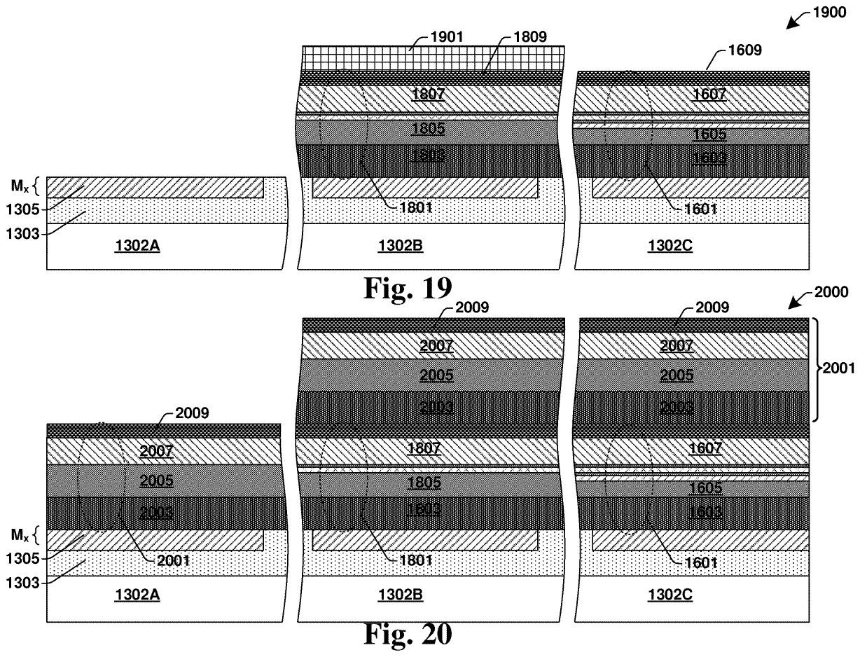

As shown by the cross-sectional view 1900 of FIG. 19, a mask 1901 is formed and used to cover the substrate region 1302B while the gate stack 1801 is etched from the substrate regions 1302A and 1302C. Over the substrate regions 1302C, the etch stops on the hard mask layer 1609. After etching, the mask 1901 is stripped.

As shown by the cross-sectional view 2000 of FIG. 20, a gate stack 2001 is formed over the structure shown by the cross-sectional view 1900 of FIG. 19. The gate stack 2001 includes an electrode layer 2003, a gate dielectric layer 2005, a channel layer 2007, and a hard mask layer 2009.

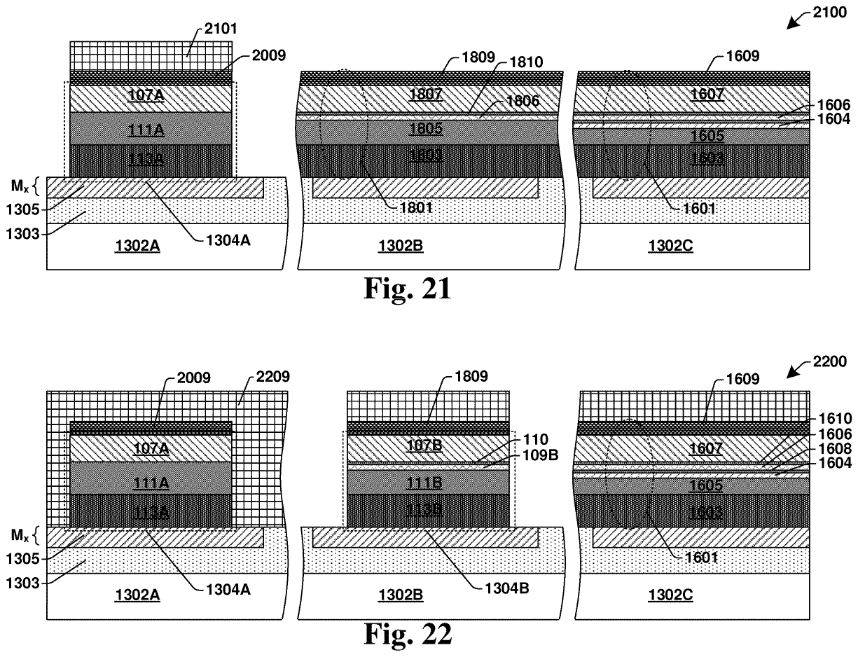

As shown by the cross-sectional view 2100 of FIG. 21, a mask 2101 is formed and used to pattern the bottom gate transistor 1304A from the gate stack 2001 in the substrate region 1302A while the gate stack 2001 is etched from the substrate regions 1302B and 1302C. Over the substrate regions 1302B, the etch stops on the hard mask layer 1809. Over the substrate regions 1302C, the etch stops on the hard mask layer 1609. Patterning the bottom gate transistor 1304A includes patterning the bottom gate electrode 113A from the electrode layer 2003, the gate dielectric 111A from the gate dielectric layer 2005, and the channel layer 107A from the channel layer 2007.

As shown by the cross-sectional view 2200 of FIG. 22, a mask 2209 is formed and used to pattern the gate stack 1801 in the substrate region 1302B while covering the substrate regions 1302A and 1302C. In the substrate region 1302B etching defines the bottom gate transistor 1304B, which includes patterning the bottom gate electrode 113B from the electrode layer 1803, the gate dielectric 111B from the gate dielectric layer 1805, the buried layer 109B from the first buried layer 1806, the thin layer 110 from the first thin gate dielectric layer 1810, and the channel layer 107B from the channel layer 1807.

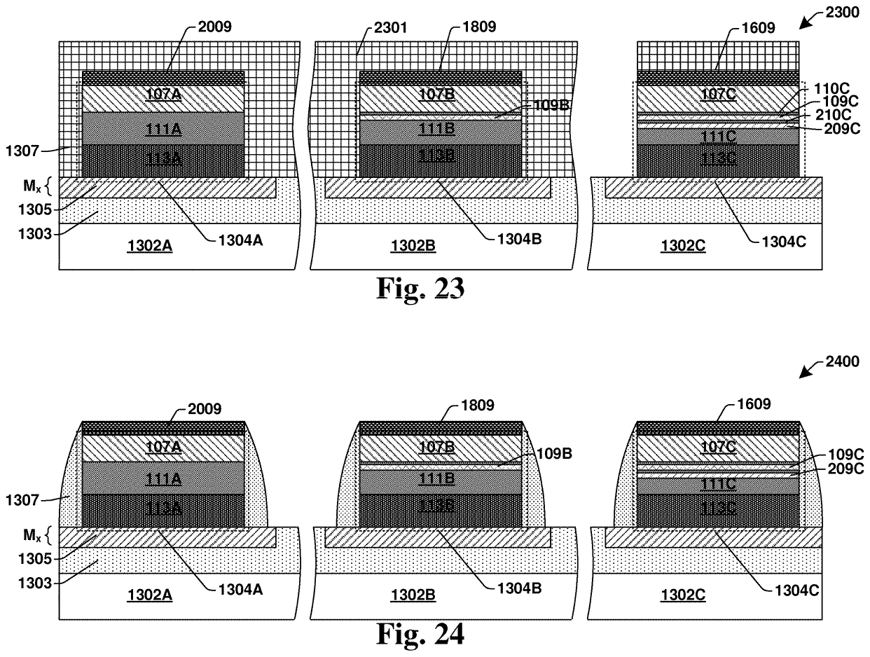

As shown by the cross-sectional view 2300 of FIG. 23, a mask 2301 is formed and used to pattern the gate stack 1601 in the substrate region 1302C while covering the substrate regions 1302A and 1302B. In the substrate region 1302C etching defines the bottom gate transistor 1304C, which includes patterning the bottom gate electrode 113C from the electrode layer 1603, the gate dielectric 111C from the gate dielectric layer 1605, the second buried layer 209C from the second buried layer 1604, the second thin layer 210C from the second thin gate dielectric layer 1608, the first buried layer 109C from the first buried layer 1606, the first thin layer 110C from the first thin gate dielectric layer 1610, and the channel layer 107C from the channel layer 1607. In view of the similarity between the gate stack 1801 and the gate stack 1601, the etches of FIGS. 22 and 23 may be combined into a single patterning process.

As shown by the cross-sectional view 2400 of FIG. 24, sidewall spacers 1307 may be formed around the bottom gate transistors 1304A, 1304B, and 1304C. Sidewall spacers 1307 may be a nitride, a carbide, an oxide, the like, a combination thereof, or any other suitable dielectric structure. Sidewall spacers 1307 may be formed by deposition followed by etching. The spacer material may be deposited by CVD, PVD, or the like.

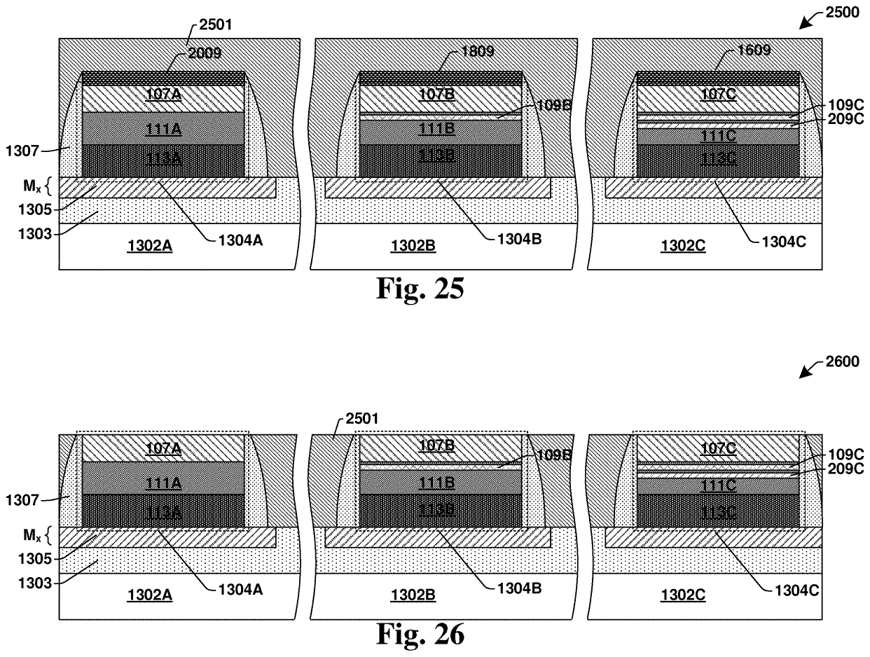

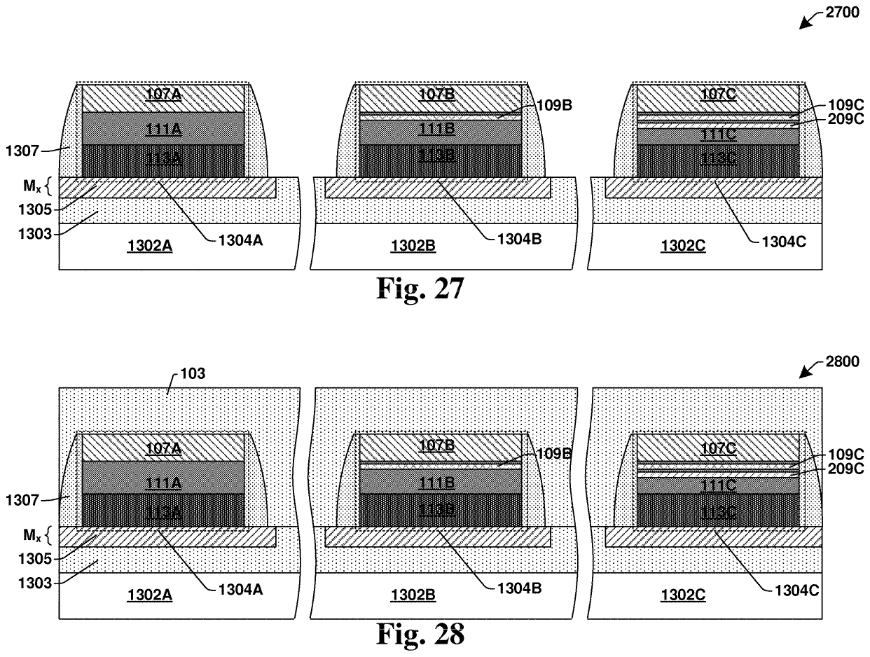

As shown by the cross-sectional view 2500 of FIG. 25, an anti-reflective coating (ARC) 2501 or other suitable fill material is deposited over the structure by the cross-sectional view 2400 of FIG. 24. The ARC 2501 fills gaps between the bottom gate transistors 1304A, 1304B, and 1304C. As shown by the cross-sectional view 2600 of FIG. 26, planarization may then be carried out. The planarization process may be chemical mechanical polishing (CMP) or the like. Planarization removes the hard mask layers 1609, 1809, and 2009. As shown by the cross-sectional view 2700 of FIG. 27, after planarization the ARC 2501 is stripped.

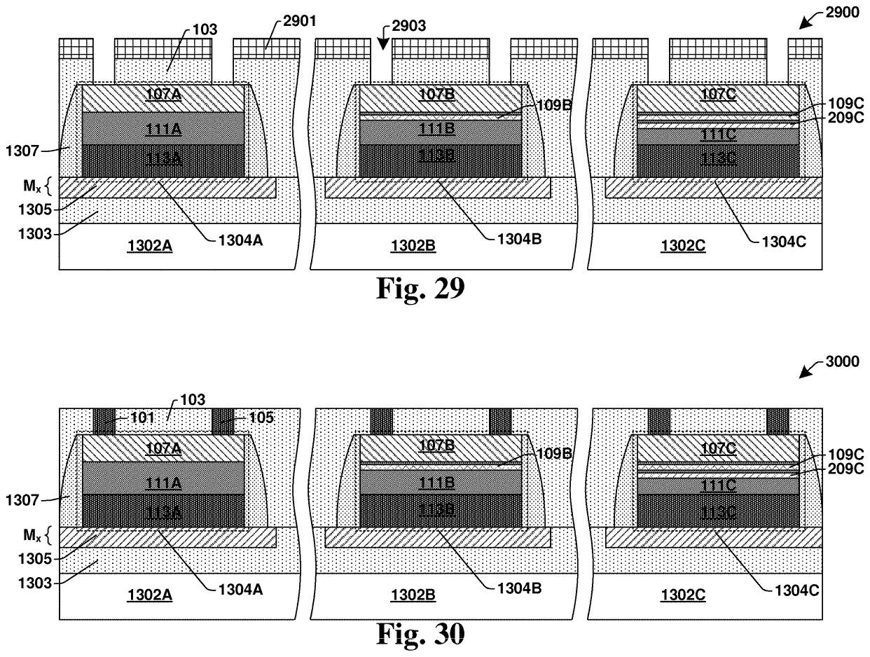

As shown by the cross-sectional view 2800 of FIG. 28, the ILD layer 103 may then be deposited. The ILD layer 103 may be silicon oxide (SiO), a low-κ dielectric, the like, of any other suitable dielectric. The ILD layer 103 may be formed by CVD, PVD, or any other suitable process. As shown by the cross-sectional view 2900 of FIG. 29, a mask 2901 may be formed and used to etch openings 2903 in the ILD layer 103. As shown by the cross-sectional view 3000 of FIG. 30, the openings 2903 may be filled with conductive material to form the source regions 101 and the drain regions 105. The conductive material may be a metal, the like, or any other suitable conductive material.

An interlevel dielectric layer 1311, vias 1309, and a metallization layer M_{X+1} may be formed over the structure shown by the cross-sectional view 3000 of FIG. 30 to produce an IC device like the IC device 1300 of FIG. 13. Vias 1309 couple the source regions 101 and the drain regions 105 to metal lines 1314 in the metallization layer M_{X+1}.

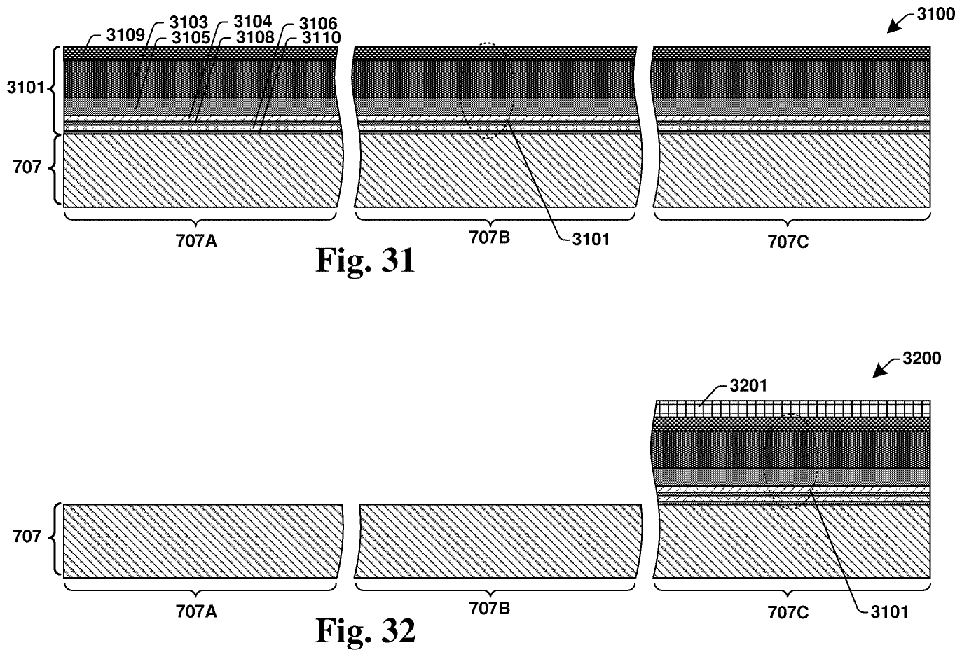

FIGS. 31 through 41 are cross-sectional view illustrations exemplifying a method according to the present disclosure of forming an IC device having top gate transistors according to the present disclosure. While FIGS. 31 through 41 are described with reference to various embodiments of a method, it will be appreciated that the structures shown in FIGS. 31 through 41 are not limited to the method but rather may stand alone separate from the method. FIGS. 31 through 41 are described as a series of acts. The order of these acts may be altered in other embodiments. While FIGS. 31 through 41 illustrate and describe a specific set of acts, some may be omitted in other embodiments. Further, acts that are not illustrated and/or described may be included in other embodiments. While the method of FIGS. 31 through 41 is described in terms of forming the IC device 1400 of FIG. 14 or the like, the method and variations thereof may be used to form other IC devices.

As shown by the cross-sectional view 3100 of FIG. 31, the process begins with forming a gate stack 3101 over the semiconductor substrate 707. The gate stack 3101 includes layers corresponding to the top gate transistor 800 of FIG. 8. The gate stack 3101 includes a first thin gate dielectric layer 3110, a first buried layer 3106, a second thin gate dielectric layer 3108, a second buried layer 3104, a gate dielectric layer 3105, an electrode layer 3103, and a hard mask layer 3109. These layers may be produced by PVD, CVD, ALD, the like, or any other suitable processes.

As shown by the cross-sectional view 3200 of FIG. 32, a mask 3201 may be used to cover the substrate region 707C while the gate stack 3101 is etched from the substrate region 707A and the substrate region 707B. After etching, the mask 3201 is stripped.

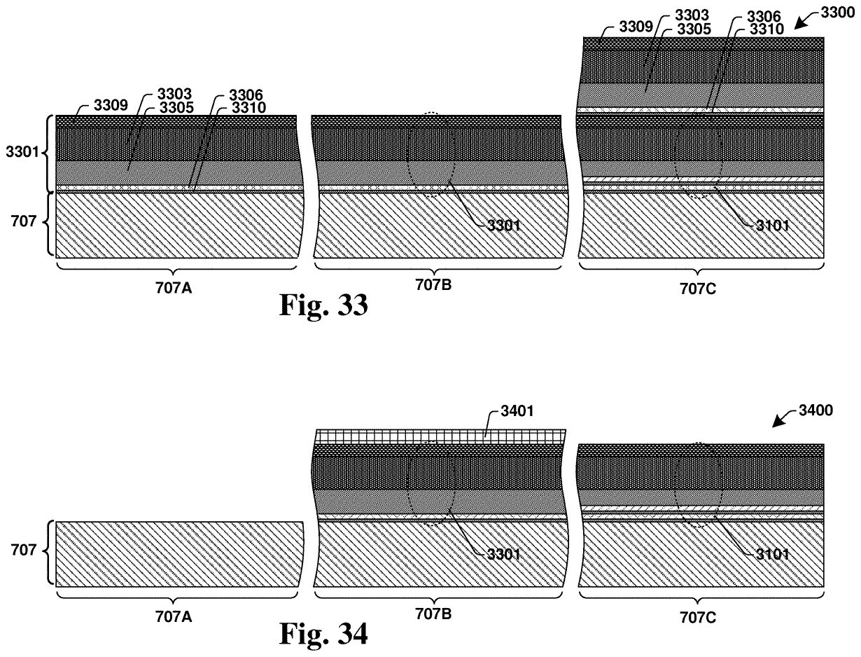

As shown by the cross-sectional view 3300 of FIG. 33, a gate stack 3301 is formed over the structure shown by the cross-sectional view 3200 of FIG. 32. The gate stack 3301 includes layers corresponding to the top gate transistor 700 of FIG. 7. The gate stack 3301 includes a first thin gate dielectric layer 3310, a first buried layer 3306, a gate dielectric layer 3305, an electrode layer 3303, and a hard mask layer 3309.

As shown by the cross-sectional view 3400 of FIG. 34, a mask 3401 may be used to cover the substrate region 707B while the gate stack 3301 is etched from the substrate region 707A and the substrate region 707C. After etching, the mask 3401 is stripped.

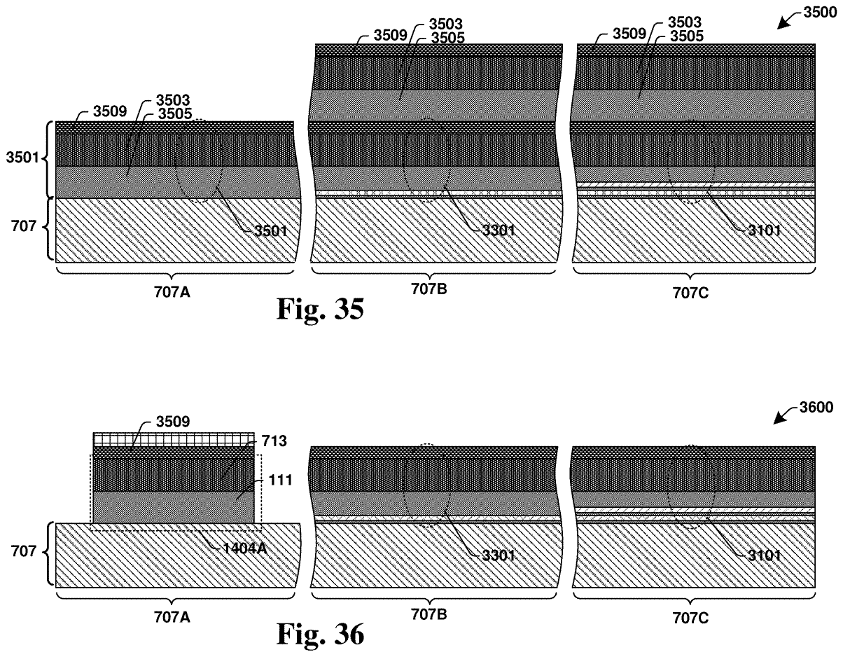

As shown by the cross-sectional view 3500 of FIG. 35, a gate stack 3501 is formed over the structure shown by the cross-sectional view 3200 of FIG. 32. The gate stack 3501 includes layers corresponding to the top gate transistor 700 of FIG. 7. The gate stack 3501 includes a gate dielectric layer 3505, an electrode layer 3503, and a hard mask layer 3509.

As shown by the cross-sectional view 3600 of FIG. 36, a mask 3601 is used to pattern the top gate transistor 1404A from the gate stack 3501 in the the substrate region 707A while the gate stack 3501 is etched from the substrate region 707B and the substrate region 707C. After etching, the mask 3401 is stripped.

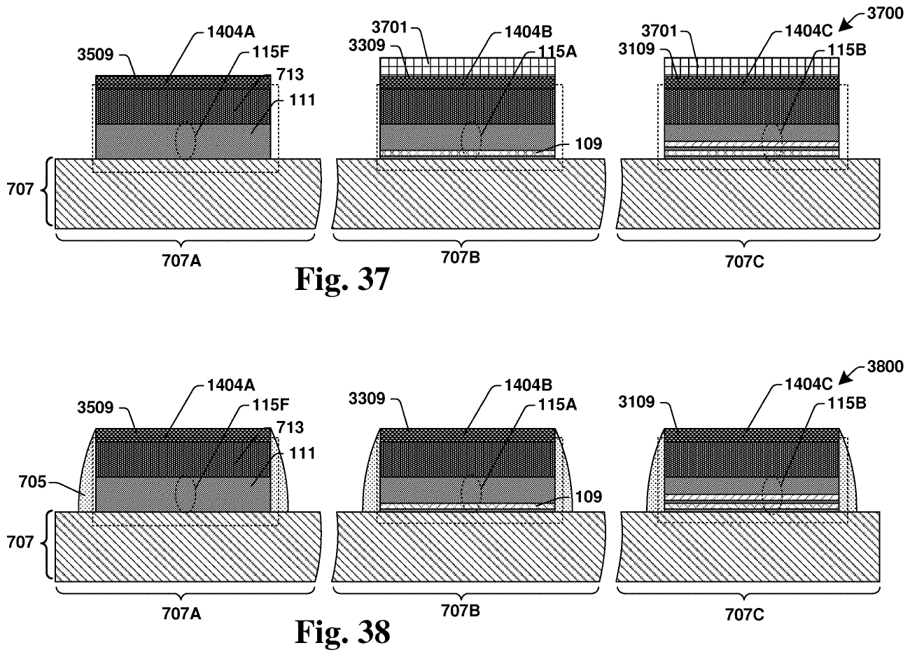

As shown by the cross-sectional view 3700 of FIG. 37, a mask 3701 is used to cover the top gate transistor 1404A in the substrate region 707A while patterning the transistor 1404B from the gate stack 3301 in the substrate region 707B and the transistor 1404C from the gate stack 3101 in the substrate region 707C. After patterning, the mask 3701 is stripped.

As shown by the cross-sectional view 3800 of FIG. 38, sidewall spacers 705 may be formed around the top gate transistors 1404A, 1404B, and 1404C. Sidewall spacers 705 are a nitride, a carbide, an oxide, the like, a combination thereof, or any other suitable dielectric. Sidewall spacers 705 may be formed by deposition followed by etching. The spacer material may be deposited by CVD, PVD, or the like.

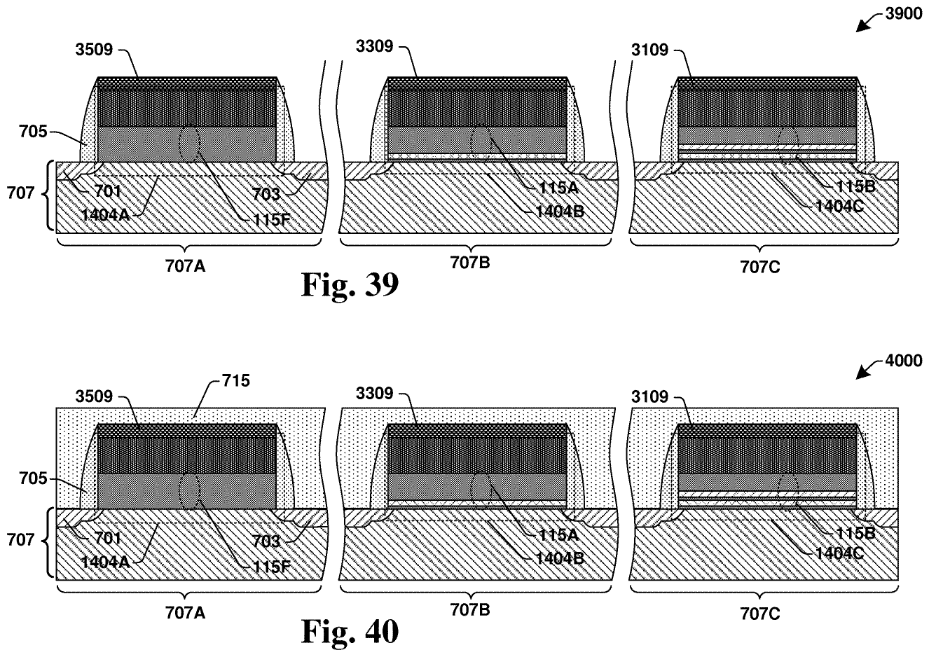

As shown by the cross-sectional view 3900 of FIG. 39, source regions 701 and drain regions 703 may be formed by doping the semiconductor substrate 707 in alignment with the sidewall spacers 705. Doping my include ion implantation followed by annealing.

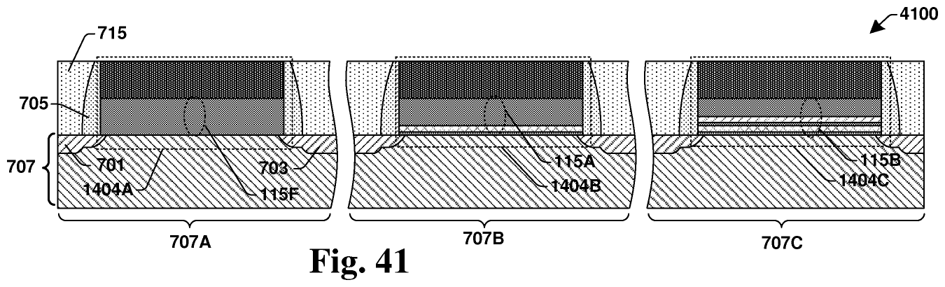

As shown by the cross-sectional view 4000 of FIG. 40, the ILD layer 715 may be deposited over the structure shown by the cross-sectional view 3900 of FIG. 39. As shown by the cross-sectional view 4100 of FIG. 41, a planarization may then be used to remove the hard mask layers 3109, 3309, and 3509.

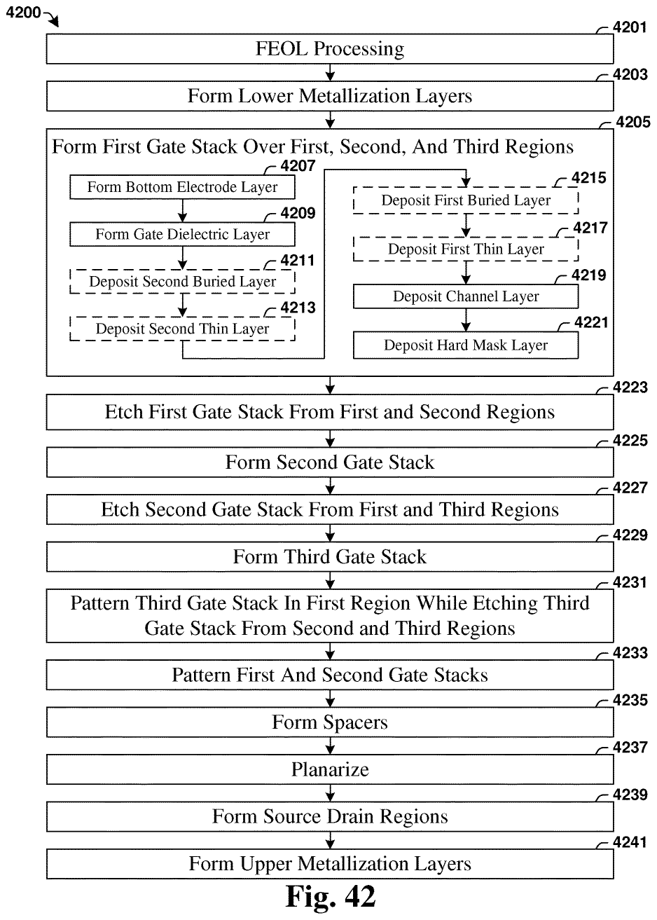

FIG. 42 presents a flow chart for a process 4200 that may be used to form an IC device with bottom gate transistors according to the present disclosure. While the process 4200 of FIG. 42 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts are required to implement one or more aspects or embodiments of the description herein, and one or more of the acts depicted herein may be carried out in one or more separate acts and/or phases.

The process 4200 may begin with act 4201, front end of line (FEOL) processing and may continue with act 4203, forming a few metallization layers. The cross-sectional view 1500 of FIG. 15 provides an example.

Act 4205 is forming the first gate stack. The first gate stack, and all other depositions, extend over first, second, and third regions of the substrate. Forming the first gate stack includes act 4207, forming a bottom electrode layer, act 4209, forming a gate dielectric layer, act 4219, forming a channel layer, and act 4221, forming a hard mask layer. Act 4205 may optionally include one or more of act 4211, depositing a second buried layer, act 4213, depositing a second thin layer, act 4215, depositing a first buried layer, and act 4217, depositing a first thin layer. Depositing the thin layers may comprise depositing a few Angstroms of the material of the gate dielectric layer. By suitable selection among these optional acts, gate stacks corresponding to any of the transistors 100, 200, 400, 500, or 600 of FIGS. 1-2 and 4-6 may be formed. The cross-sectional view 1600 of FIG. 16 provides an example of act 4205.

Act 4223 is etching the first gate stack from the first and second regions. The cross-sectional view 1700 of FIG. 17 provides an example.

Act 4225 is forming the second gate stack. Act 4225 is like act 4205 but may use different selections among the optional steps and may use different layer compositions or thicknesses. The cross-sectional view 1800 of FIG. 18 provides an example.

Act 4227 is etching the second gate stack from the first and third regions. The cross-sectional view 1900 of FIG. 19 provides an example.

Act 4229 is forming the third gate stack. Act 4229 is like act 4205 but may use different selections among the optional steps and may use different layer compositions or thicknesses. The cross-sectional view 2000 of FIG. 20 provides an example.

Act 4231 is patterning the third gate stack in the first region while etching the third gate stack from the second and third regions. The cross-sectional view 2100 of FIG. 21 provides an example.

Act 4233 is patterning the first gate stack in the third region and patterning the second gate stack in the second region. This patterning may be done with one patterning process or two. The cross-sectional views 2200 and 2300 of FIGS. 22 and 23 provide an example.

Act 4235 is forming spacers adjacent the transistors that result from patterning the first, second, and third gate stacks. The cross-sectional view 2400 of FIG. 24 provides an example.

Act 4237 is planarization to remove the hard mask layers from the transistors. Before planarization, a material is deposited to fill spaces between the transistors. The fill material may be an ILD layer or a temporary material, such as an ARC coating, that may be removed after planarization. The cross-sectional views 2500-2700 of FIGS. 25-27 provide an example.

Act 4239 is forming source and drain regions over the gate electrodes of the transistors. This may include depositing an ILD layer, etching openings in the ILD layer, and filling the openings with metal or other conductive material to provide the source and drain regions. The cross-sectional views 2800-3000 of FIGS. 28-30 provide an example.

Act 4241 is forming upper metallization layer that include contacts with the source and drain regions. The IC device 1300 of FIG. 13 provides an example of the resulting structure.

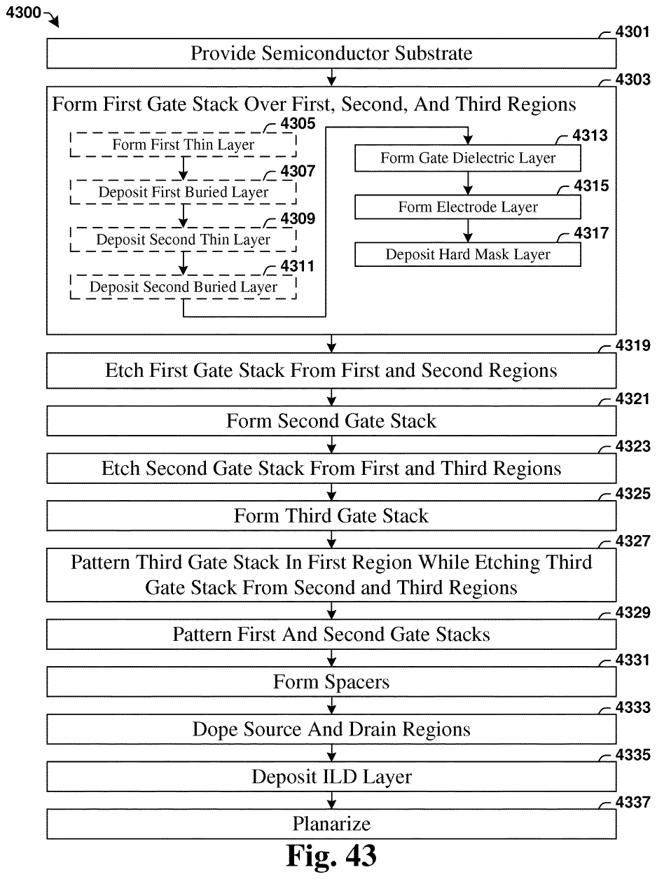

FIG. 43 presents a flow chart for a process 4300 that may be used to form an IC device with top gate transistors according to the present disclosure. While the process 4300 of FIG. 43 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts are required to implement one or more aspects or embodiments of the description herein, and one or more of the acts depicted herein may be carried out in one or more separate acts and/or phases.

The process 4300 may begin with act 4301, providing a semiconductor substrate and act 4303, forming a first gate stack over that substrate. Forming the first gate stack includes act 4313, forming a gate dielectric layer, act 4315, forming an electrode layer, and act 4317, forming a hard mask layer. Act 4303 may optionally include one or more of act 4305, forming a first thin layer, act 4307, depositing a first buried layer, act 4309, depositing a second buried layer, act 4311, depositing a second thin layer. The cross-sectional view 3100 of FIG. 31 provides an example Depositing the thin layers may comprise depositing a few Angstroms of the material of the gate dielectric layer. By suitable selection among these optional acts, gate stacks corresponding to any of the transistors 700, 800, 1000, 1100, or 1200 of FIGS. 7-8 and 10-12 may be formed.

Act 4319 is etching the first gate stack from the first and second regions. The cross-sectional view 3200 of FIG. 32 provides an example.

Act 4321 is forming the second gate stack. The cross-sectional view 3300 of FIG. 33 provides an example. Act 4321 is like act 4303 but may use different selections among the optional steps and may use different layer compositions or thicknesses.

Act 4323 is etching the second gate stack from the first and third regions. The cross-sectional view 3400 of FIG. 34 provides an example.

Act 4325 is forming the third gate stack. The cross-sectional view 3500 of FIG. 35 provides an example. Act 4325 is like act 4303 but may use different selections among the optional steps and may use different layer compositions or thicknesses.

Act 4327 is patterning the third gate stack in the first region while etching the third gate stack from the second and third regions. The cross-sectional view 3600 of FIG. 36 provides an example.

Act 4329 is patterning the first gate stack in the third region and patterning the second gate stack in the second region. This patterning may be done with one patterning process or two. The cross-sectional view 3700 of FIG. 37 provides an example.

Act 4331 is forming spacers adjacent the transistors that result from patterning the first, second, and third gate stacks. The cross-sectional view 3800 of FIG. 38 provides an example.

Act 4333 is doping to form source and drain regions aligned to the spacers. The cross-sectional view 3900 of FIG. 39 provides an example.

Act 4335 is depositing an ILD layer over the transistors. The cross-sectional view 4000 of FIG. 40 provides an example.

Act 4337 is planarization to remove the hard mask layers from the transistors. The cross-sectional view 4100 of FIG. 41 provides an example.

Some aspects of the present disclosure relate to an integrated circuit device that includes a transistor having a gate electrode, a gate dielectric, and a semiconductor channel. The gate dielectric is between the gate electrode and the semiconductor channel. A second dielectric layer embedded in the gate dielectric. The second dielectric layer has a higher dielectric constant than the gate dielectric.

In some embodiments, the second dielectric layer is closer to the semiconductor channel than to the gate electrode. In some embodiments, a thickness of the second dielectric layer is less than a distance from the second dielectric layer to the gate electrode. In some embodiments, the gate dielectric and the second dielectric are oxides. In some embodiments, the gate dielectric is silicon oxide (SiO2). In some embodiments, the second dielectric layer is a mixture of two dielectric. The two dielectrics have oxygen areal densities that are either both higher or both lower than an oxygen areal density of the gate dielectric. In some embodiments, a third dielectric layer embedded in the gate dielectric. The third dielectric layer has a higher dielectric constant than the gate dielectric. In some embodiments, a thin layer of the gate dielectric separates the second dielectric layer and the third dielectric layer.

In some embodiments, the gate dielectric and the second dielectric layer have an electronegativity difference that is greater than the electronegativity difference between silicon dioxide and hafnium oxide. In some embodiments, the gate dielectric and the second dielectric layer have an oxygen areal density difference that is greater than the oxygen areal density difference between silicon dioxide and hafnium oxide. In some embodiments, the semiconductor channel is above the semiconductor channel. In some embodiments, the semiconductor channel is below the semiconductor channel.

Some aspects of the present disclosure relate to an integrated circuit device that includes a transistor having a gate electrode, a gate dielectric structure, and a semiconductor channel. The gate dielectric structure comprises a first dielectric layer and a second dielectric layer. The first dielectric layer is at least half a thickness of the gate dielectric structure and is between the second dielectric layer and the gate electrode. The second dielectric layer has a higher dielectric constant than the first dielectric layer.

In some embodiments, the second dielectric layer is spaced apart from the semiconductor channel. In some embodiments, the gate dielectric structure further includes a third dielectric layer. The third dielectric layer has a distinct composition from the first dielectric layer and the second dielectric layer and has a higher dielectric constant than the first dielectric layer. In some embodiments, the third dielectric layer is spaced apart from the second dielectric layer. In some embodiments, the second dielectric layer comprises a mixture of two dielectrics having higher dielectric constants than the first dielectric layer.

Some aspects of the present disclosure relate to an integrated circuit device that includes a transistor having a gate electrode, a gate dielectric structure, and a semiconductor channel. The gate dielectric structure includes a first dielectric layer and a second dielectric layer. A first interface between the first dielectric layer and the second dielectric layer is closer to the semiconductor channel than to the gate electrode. The compositions of the first dielectric layer and the second dielectric layer are such that electrical dipoles form in the gate dielectric structure proximate the first interface. The electrical dipoles significantly affect a threshold voltage of the transistor.

Some aspects of the present disclosure relate to method that includes forming a dielectric structure between a semiconductor and a gate electrode. Forming the dielectric structure includes embedding a high-κ dielectric layer within a gate dielectric. The high-κ dielectric has a higher dielectric constant than the gate dielectric. In some embodiments, embedding the high-κ dielectric layer within the gate dielectric includes depositing a first layer of the gate dielectric, depositing the high-κ dielectric layer over the first layer, and depositing a second layer of the gate dielectric over the high-κ dielectric layer. In some embodiments, the high-κ dielectric layer is thinner than the gate dielectric and is closer to the semiconductor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a transistor having a gate electrode, a gate dielectric, and a semiconductor channel, wherein the gate dielectric is between the gate electrode and the semiconductor channel; and
a second dielectric layer embedded in the gate dielectric wherein the second dielectric layer has a higher dielectric constant than the gate dielectric.

2. The integrated circuit device of claim 1, wherein the second dielectric layer is closer to the semiconductor channel than to the gate electrode.

3. The integrated circuit device of claim 1, wherein a thickness of the second dielectric layer is less than a distance from the second dielectric layer to the gate electrode.

4. The integrated circuit device of claim 1, wherein the gate dielectric and the second dielectric layer comprise oxides.

5. The integrated circuit device of claim 4, wherein the gate dielectric comprises silicon dioxide.

6. The integrated circuit device of claim 1, wherein:
the second dielectric layer comprises a second dielectric mixed with a third dielectric; and
the second dielectric and the third dielectric have oxygen areal densities that are either both higher than an oxygen areal density of the gate dielectric or both lower than then the oxygen areal density of the gate dielectric.

7. The integrated circuit device of claim 1, further comprising a third dielectric layer embedded in the gate dielectric, wherein the third dielectric layer has a higher dielectric constant than the gate dielectric.

8. The integrated circuit device of claim 7, wherein a thin layer of the gate dielectric separates the second dielectric layer and the third dielectric layer.

9. The integrated circuit device of claim 1, wherein the gate dielectric and the second dielectric layer have an electronegativity difference that is greater than the electronegativity difference between silicon dioxide and hafnium oxide.

10. The integrated circuit device of claim 1, wherein the gate dielectric and the second dielectric layer have an oxygen areal density difference that is greater than the oxygen areal density difference between silicon dioxide and hafnium oxide.

11. The integrated circuit device of claim 1, wherein the semiconductor channel is above the semiconductor channel.

12. The integrated circuit device of claim 1, wherein the semiconductor channel is below the semiconductor channel.

13. An integrated circuit device, comprising:
a transistor having a gate electrode, a gate dielectric structure, and a semiconductor channel;
wherein the gate dielectric structure comprises a first dielectric layer and a second dielectric layer;
the first dielectric layer is at least half a thickness of the gate dielectric structure and is between the second dielectric layer and the gate electrode; and
the second dielectric layer has a higher dielectric constant than the first dielectric layer.

14. The integrated circuit device of claim 13, wherein the second dielectric layer is spaced apart from the semiconductor channel.

15. The integrated circuit device of claim 13, wherein:
the gate dielectric structure further comprises a third dielectric layer;
the third dielectric layer has a distinct composition from the first dielectric layer and the second dielectric layer; and
the third dielectric layer has a higher dielectric constant than the first dielectric layer.

16. The integrated circuit device of claim 15, wherein the third dielectric layer is spaced apart from the second dielectric layer.

17. The integrated circuit device of claim 15, wherein the second dielectric layer comprises a mixture of two dielectrics having higher dielectric constants than the first dielectric layer.

18. A method comprising:
forming a dielectric structure between a semiconductor and a gate electrode;
wherein forming the dielectric structure comprising embedding a high-κ dielectric layer within a gate dielectric; and
the high-κ dielectric has a higher dielectric constant than the gate dielectric.

19. The method of claim 18, wherein embedding the high-κ dielectric layer within the gate dielectric comprises:
depositing a first layer of the gate dielectric;
depositing the high-κ dielectric layer over the first layer; and
depositing a second layer of the gate dielectric over the high-κ dielectric layer.

20. The method of claim 19, wherein the high-κ dielectric layer is thinner than the gate dielectric, and the high-κ dielectric layer is closer to the semiconductor than to the gate electrode.
